(19) United States
(12) Patent Application Publication
(10) Pub. No.: US 2026/0113841 A1
(43) Pub. Date: Apr. 23, 2026

(54) PRINTED CIRCUIT BOARD ASSEMBLY

(71) Applicant: Rolls-Royce Deutschland Ltd & Co KG, Blankenfelde-Mahlow (DE)

(72) Inventors: Uwe WALTRICH, Forchheim (DE); Niklas SCHAMBERGER, Nürnberg (DE); Dipenkumar PATEL, Erlangen (DE)

(21) Appl. No.: 19/362,338

(22) Filed: Oct. 17, 2025

(30) Foreign Application Priority Data
Oct. 22, 2024 (DE) 10 2024 130 700.5

(51) Int. Cl. H05K 1/11; H05K 1/18

(52) U.S. Cl. CPC H05K 1/111; H05K 1/181; H05K 2201/09409

(57) ABSTRACT

A printed circuit board assembly includes a printed circuit board having an upper side and a lower side, and an electrical module having an upper side and a lower side. The upper side of the electrical module is electrically connected to the lower side of the printed circuit board. For the electrical module to make electrical contact, the electrical module has electrical contacts on the upper side of the electrical module. An underfill material is arranged between the upper side of the electrical module and the lower side of the printed circuit board in an area next to the electrical contacts. Each of the electrical contacts is arranged adjacent to a side edge of the upper side of the electrical module, and an edge gap between the respective electrical contact and the adjacent side edge is sealed by an edge bond material.

### PRIORITY

This application claims the benefit of the German patent application DE 102024130700.5, filed on Oct. 22, 2024, which is hereby incorporated by reference in its entirety.

### BACKGROUND

### Technical Field

The present disclosure relates to a printed circuit board assembly.

### Description of the Related Art

It is known to arrange printed circuit board-based power electronics components as electrical modules on the lower side of a printed circuit board or circuit board. This creates a gap between the upper side of the electrical modules and the printed circuit board. In that gap, there are high electrical field strengths that may lead to surface or partial discharges that in turn may lead to degradation of the printed circuit board material. It is further known to apply an underfill material in the gap between the electrical module and the printed circuit board in order to avoid partial discharges and to comply with requirements for clearance and creepage distances.

The corresponding underfill process includes applying a defined amount of an underfill material along at least one side of the respective module, the underfill material spreads into the gap through capillary action. In this case, there is the problem that air pockets may form when the underfill material spreads, that air pockets in turn lead to partial discharges and involve the risk of early insulation failure. There is an increased monitoring effort linked to the manufacturing and an increased discard rate.

### SUMMARY AND DESCRIPTION

The scope of the present disclosure is defined solely by the appended claims and is not affected to any degree by the statements within this summary.

There is a need to provide a printed circuit board assembly that reduces the risk of air bubbles being created in the underfill process.

In a first aspect a printed circuit board assembly is provided. The printed circuit board assembly includes a printed circuit board having an upper side and a lower side, and an electrical module having an upper side and a lower side. The upper side of the electrical module is electrically connected to the lower side of the printed circuit board. For the electrical module to make electrical contact, the electrical module has electrical contacts on its upper side, and an underfill material is arranged between the upper side of the electrical module and the lower side of the printed circuit board in the area next to the electrical contacts.

Provision is made for the electrical contacts to each be arranged adjacent to a side edge of the upper side of the electrical module, and for an edge gap between the respective electrical contact and the adjacent side edge to be sealed by an edge bond material.

The edge bond material may be an electrically non-conductive adhesive that is applied to the edges of the electrical contacts and seals the area up to the side border, with the result that no underfill material may flow in this area. The edge bond material is used to protect against mechanical loading.

The disclosure is based on the finding that the air situated between the electrical module and the printed circuit board may be displaced by the underfill material during the application process. If the underfill material spreads around an electrical contact from multiple sides, the case may arise where flow fronts of the underfill volume collide with each other. The air situated between the flow fronts cannot escape since it is trapped between the flow fronts.

The solution avoids such scenarios. Arranging the electrical contacts adjacent to a side edge and simultaneously sealing an edge gap between the respective electrical contact and the side edge by an edge bond material provides that the spreading of underfill material is blocked on that side of the electrical contact facing the side edge. The arrangement of the electrical contact and of the edge bond material thus provides sealing of the flow path of the underfill volume in the edge region, as a result of that the underfill material may only spread along the other sides.

The solution allows for directed spreading of the underfill material in the gap between the electrical module and the printed circuit board with only one flow front. The collision of flow fronts spreading in opposite flow directions and an associated air pocket are prevented. For example, the edge bond material is a different material than the underfill material. For example, the edge bond material only seals the edge gap and/or is not located in other areas on the top side of the electrical module.

A further advantage is that the underfill material only needs to be applied from one side due to the uniform flow front. As a result of this, the application process is simplified.

With the terminology used, the side of the printed circuit board on which the electrical modules are arranged is referred to as the lower side, regardless of the actual spatial orientation of the printed circuit board and of the electrical modules.

In some embodiments, the electrical contacts is formed as strips or to be strip-shaped, and the strips have the same spatial orientation. The formation of strips promotes the spreading of the underfill material along a uniform flow front during the application process.

In some embodiments, the strips may have the same width and length, unlike a traditional design of the electrical contacts, in that, for example, drain contacts, source contacts and gate contacts each have a different size.

In some embodiments, the adjacent strips may each have the same distance to each other, with the result that the underfill material spreads between the strip-shaped contacts in each case in a flow channel of the same size, this further homogenizing the spreading of the underfill material.

In some embodiments, the electrical contacts are arranged offset to each other in the sense that one of the electrical contacts is arranged adjacent to a first side edge of the upper side of the electrical module, and at least one adjacent electrical contact is arranged adjacent to the opposite side edge of the upper side of the electrical module. The arrangement of the electrical contacts offset in this sense leads to a snake-like gap geometry that further improves the formation of a single flow front.

In some embodiments, three electrical contacts are formed on the upper side of the electrical module, in particular a first electrical contact for a drain connection, a second electrical contact for a source connection and a third electrical contact for a gate connection. A semiconductor component may make electrical contact.

In some embodiments, the electrical contacts are formed, as solder pads, in order for the electrical contacts to be electrically connected to corresponding electrical contacts on the lower side of the printed circuit board; a solder material (e.g., solder balls) is applied. The electrical contacts are connected by sintering to corresponding electrical contacts on the lower side of the printed circuit board, for example by a silver sintering process.

The electrical contacts of the printed circuit board and electrical module may be formed, for example, as contact surfaces made of copper or alternatively of another metal such as aluminum or silver. The contact surfaces made of copper may be additionally metallized, for example with a gold or silver layer.

In some embodiments, the electrical contacts are arranged such that when an underfill material that is still liquid is applied, the underfill material fills the gap between the upper side of the electrical module and the lower side of the printed circuit board in only one direction.

In some embodiments, the electrical contacts are arranged in such a way that when the underfill material that is still liquid is applied, the underfill material fills the gap between the upper side of the electrical module and the lower side of the printed circuit board in the direction of the strips.

In some embodiments, the electrical contacts are arranged in such a way that when the underfill material that is still liquid is applied, the underfill material fills the gap between the upper side of the electrical module and the lower side of the printed circuit board transversely to the direction of the strips. The single flow front proceeds in a snake-like manner during application.

In some embodiments, the electrical contacts arranged on the lower side of the printed circuit board are formed with an arrangement that corresponds to the arrangement of the electrical contacts on the upper side of the electrical module. The electrical contacts on the lower side of the printed circuit board may also be formed larger than the electrical contacts on the upper side of the electrical module.

In some embodiments, the edge bond material may consist of any suitable material. The edge bond material may consist of the groups of epoxy resins, acrylic resins, polyurethanes or silicones.

In some embodiments, the printed circuit board assembly has a plurality of individual electrical modules that together include an electrical circuit such as, for example, a power converter.

In some embodiments, the electrical module includes: a ceramic circuit carrier that has an insulating ceramic layer and an upper metallization layer arranged on the upper side of the ceramic layer; and an electrical component that is arranged on the ceramic circuit carrier. The electrical component is electrically contacted via the upper electrical contacts of the electrical module and through-holes leading out from said electrical contacts.

In some embodiments, a lower metallization layer that forms a thermal interface between the electrical module and a heat sink may be arranged on the lower side of the ceramic layer.

In some embodiments, the ceramic circuit carrier is used to electrically insulate the electrical component from a heat sink and at the same time thermally connect the electrical component to the heat sink. The electrical component is, for example, a power semiconductor such as, e.g., a power MOSFET or an IGBT component. The ceramic circuit carrier together with the semiconductor component and a coating, e.g. made of a potting material or of a printed circuit board material, forms the electrical module. The electrical module is connected to the printed circuit board via the upper electrical contacts. Such an electrical module is also referred to as a prepackage module.

### BRIEF DESCRIPTION OF THE DRAWINGS

The printed circuit board assembly of the present disclosure will be explained in greater detail below using a plurality of example embodiments and with reference to the figures of the drawing, in which:

FIG. 1 shows a printed circuit board assembly having a printed circuit board and an electrical module arranged on the lower side of the printed circuit board, where an underfill material is arranged in a gap between the upper side of the electrical module and the lower side of the printed circuit board, and where the upper side of the electrical module has a plurality of electrical contacts;

FIG. 2 shows air pockets in the underfill material of a printed circuit board assembly of FIG. 1 that are created by opposing flow fronts;

FIG. 3 shows the arrangement of electrical contacts on the upper side of an electrical module of FIG. 1; and

FIG. 4 shows the printed circuit board assembly of FIG. 3, where an edge gap between the respective electrical contact and the adjacent side edge is additionally sealed by an edge bond material.

### DETAILED DESCRIPTION

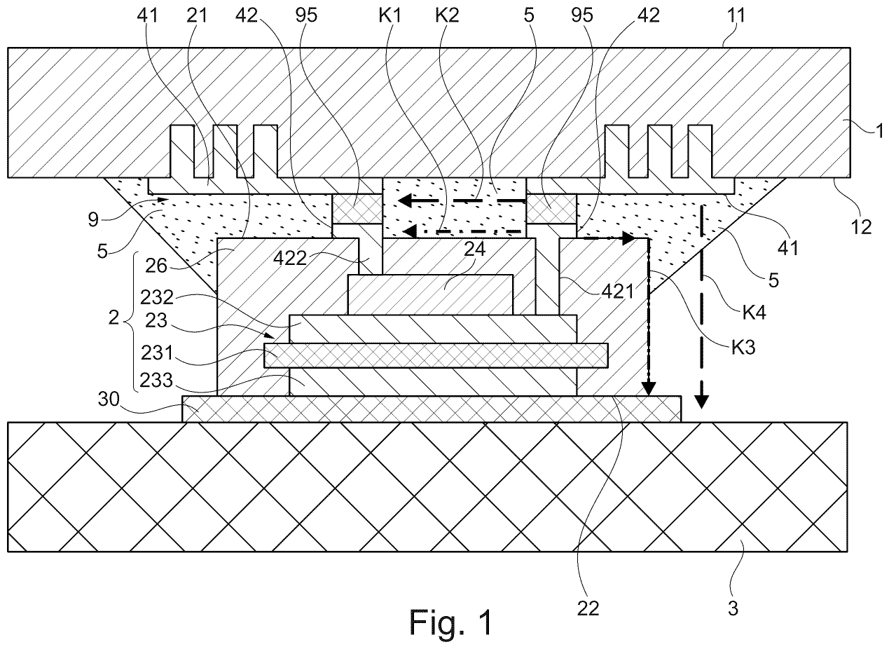

The printed circuit board assembly 1 of FIG. 1 includes a printed circuit board 1, an electrical module 2 and optionally a heat sink 3. The printed circuit board 1 is multilayered and forms, for example, a carrier board on which a multiplicity of electrical modules 2 and further components are arranged. The printed circuit board 1 forms an upper side 11 and a lower side 12. Formed on the lower side 12 are a plurality of electrical contacts 41 to each of which a defined potential, for example a high-voltage potential, is applied. The electrical contacts 41 are, for example, copper surfaces.

The electrical module 2 includes a ceramic circuit carrier 23 and an electrical component 24. The ceramic circuit carrier 23 includes an insulating ceramic layer 231, an upper metallization layer 232 arranged on the upper side of the ceramic layer 231, and an optional lower metallization layer 233 arranged on the lower side of the ceramic layer 231.

The electrical component 24 is arranged on the upper metallization layer 232. The ceramic circuit carrier 23 and the electrical component 24 are arranged in a substrate 26 that defines the external dimensions of the electrical module 2. The substrate 26 is, for example, a potting material or a printed circuit board material into which the ceramic circuit carrier and the electrical module are embedded.

The upper side 21 of the electrical module 2 has a plurality of electrical contacts 42 that are formed, for example, by copper surfaces. The upper side 21 of the electrical module 2 is soldered onto the printed circuit board 1 via surface mounting, where the contact surfaces 42 of the electrical module 2 are electrically connected to the corresponding contact surfaces 41 of the printed circuit board 1 via solder connections 95. A gap 9 between the upper side 21 of the electrical module 2 and the lower side 12 of the printed circuit board 1 forms next to or to the side of the solder connections 95. This gap 9 is filled by an underfill material 5. The underfill material 5 is applied as part of an underfill process in that a defined amount of an underfill material is applied along at least one border of the module 2, where the underfill material spreads into the gap 9 through capillary action.

The electrical contacts include through-holes 421 that extend from some of the electrical contact surfaces 42 to the upper metallization layer 233 of the ceramic circuit carrier 23, and through-holes 422 that extend from other ones of the electrical contact surfaces 42 to the upper metallization layer 232. A lower-side potential and upper-side potential of the electrical component 24 are provided via these through-holes 421, 422. For example, the through-holes 421, 422 provide a source connection, a gate connection, and a drain connection of the electrical component 24.

The lower side of the electrical module 2 that is formed by the lower metallization layer 233, is thermally coupled to the heat sink 3 via a thermal interface material 30, for example a heat conduction mat. The ceramic circuit carrier 23 having the ceramic layer 231 is used, on the one hand, to electrically insulate the electrical component 24 arranged on the ceramic circuit carrier 23 from the heat sink 3 and at the same time provides a thermal connection to the heat sink 3.

The electrical component 24 is, for example, a power semiconductor and may be formed as an integrated circuit (chip).

In such a structure, high requirements are to be implemented for clearance and creepage distances. This is related to the fact that a high-voltage potential, for example, in the region of 1000 V, is typically applied to the contact surfaces 41, 42. A strong electrical field thus exists between the contact surfaces and the heat sink 3 that is typically connected to ground. Corresponding potential creepage distances K1, K3 and clearance distances K2, K4 are depicted in FIG. 1.

In order to improve the insulation properties and to avoid partial discharges, provision is made, in a printed circuit board assembly of FIG. 1 as explained, for an underfill material 5 to be formed in the gap 9 between the lower side 12 of the printed circuit board 1 and the upper side 21 of the electrical module 2.

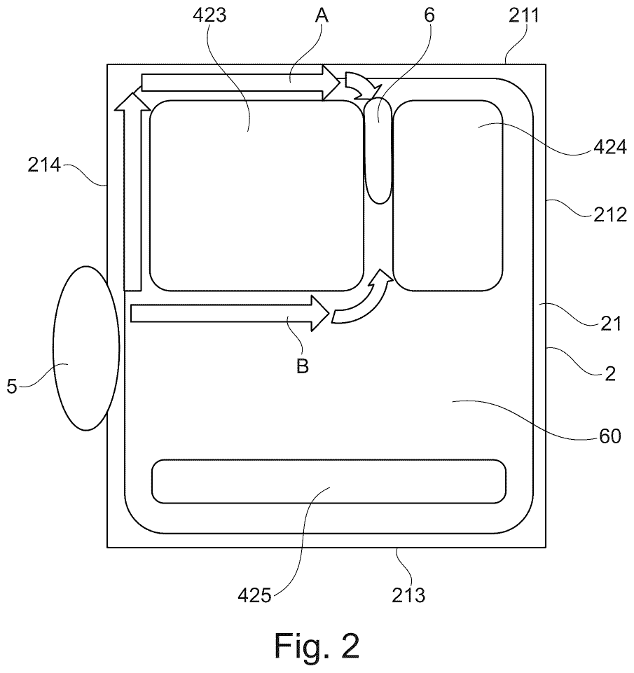

When applying an underfill material 5 in the gap 9, air pockets may occur. This is illustrated by way of example in FIG. 2. FIG. 2 shows a plan view of the upper side 21 of an electrical module 2. The electrical module 2 is rectangular and accordingly has an upper side edge 211, a lower side edge 213 and two lateral side edges 212, 214. The side edges may also be referred to as side borders.

Three electrical contacts, namely a source contact 423, a gate contact 424 and a drain contact 425, are arranged on the upper side 21 of the electrical module 2. If an underfill material 5 is now provided for filling the gap 9 at the one side border 214 of the electrical module 2, the underfill material spreads in the intermediate space or gap 9 between the upper side 21 of the electrical module 2 and the lower side 12 of the printed circuit board. In areas such as the area 60, this happens without any problems since there is a uniform flow direction of the underfill material 5. On the contrary, if the underfill material 5 forms two flow fronts that flow in opposite directions, air pockets 6 may occur. This is the case in the intermediate space between the electrical source contact 423 and the electrical gate contact 424. Here, first, the flow front A and the flow front B collide with each other, with the result that air 6 cannot escape, and an air pocket forms.

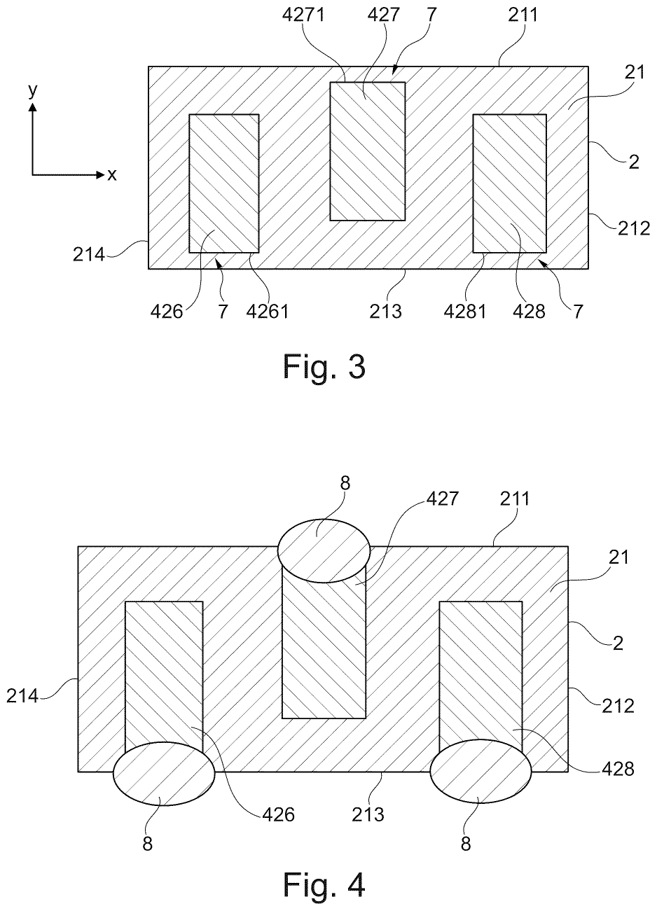

In order to avoid the situation explained in FIG. 2, the present disclosure provides an arrangement of the electrical contacts of FIGS. 3 and 4.

FIG. 3 shows three electrical contacts 426, 427, 428 that are situated on the upper side 21 of the electrical module 2 that in turn has four side edges 211, 212, 213 and 214. The electrical contacts 426, 427, 428 are arranged in such a way that the electrical contacts 426, 427, 428 are each arranged adjacent to one of the side edges, in the present case the side edges 211 or 213. An electrical drain contact 426 is situated adjacent to the side edge 213, an electrical source contact 427 is situated adjacent to the side edge 211, and an electrical gate contact 428 is situated adjacent to the side edge 213.

The arrangement adjacent to a side edge 211, 213 provides, in this case, that only a small edge gap 7 is situated between that side border of the electrical contact 426-428 lying nearest to the side edge and the side edge. An edge gap 7 is situated between the side border 4261 and the side edge 213, an edge gap 7 is situated between the side border 4271 and the side edge 211, and an edge gap 7 is situated between the side border 4281 and the side edge 213.

FIG. 4 shows the aforementioned edge gaps 7 between the respective electrical contact 426-428 and the respective side edge to be sealed by an edge bond material 8. Such an edge bond material is schematically depicted in FIG. 4. For example, the edge bond material is an epoxy resin, an acrylic resin, a polyurethane or a silicone.

FIGS. 3 and 4 show the electrical contacts 426, 427, 428 that are each strip-shaped, i.e. they are rectangular and have a larger length (in the y-direction) than width (in the x-direction), with the x-direction and the y-direction being depicted in FIG. 3. The electrical contacts 426, 427, 428 all have the same width and length. The electrical contacts 426, 427, 428 also have the same distance to each other.

The electrical contacts 426, 427, 428 are arranged offset to each other in the sense that the electrical contacts 426, 428 are arranged adjacent to the lower side edge 213 and the electrical contact 427 is arranged adjacent to the upper side edge 211.

The described arrangement of the electrical contacts 426, 427, 428 allows the gap 9 of FIG. 1 between the upper side 21 of the electrical module 2 and the lower side 12 of the printed circuit board 1 to be filled in the application process with a single flow front, with the result that the risk of air pockets is minimized. This is achieved by the described gap geometry in that no flow fronts may collide with each other.

Provision may be made for the underfill material to be applied to the upper border 211 or the lower border 213. During application to the upper border 211 with one flow front, the underfill material spreads from the upper border 211 to the lower border 212. Since the respective edge regions of the electrical contacts 426, 427, 428 to the adjacent side edge 211, 213 are sealed by the edge bond material 8, no opposing flow fronts may collide with each other there. During application to the lower border 213, the underfill material spreads from the lower to the upper border.

Provision may be made for the underfill material to be applied to one of the side borders 214, 212. A snake-shaped course of the flow front occurs. During application, for example, to the left side border 214, the underfill material first spreads in the channel between the electrical contacts 426, 427, then around the lower end of the electrical contact 427 and then in the channel between the electrical contacts 427, 428. There is only a single flow front and there is no risk of opposing flow fronts colliding.

The disclosure is not limited to the embodiments described above and different modifications and improvements may be made without deviating from the concepts described here. It is furthermore pointed out that any of the features described may be used separately or in combination with any other features, provided that they are not mutually exclusive. The disclosure extends to and includes all combinations and sub-combinations of one or more features that are described here. If ranges are defined, these ranges therefore include all of the values within these ranges as well as all of the partial ranges that lie within a range.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A printed circuit board assembly comprising:
a printed circuit board having an upper side and a lower side; and
an electrical module having an upper side and a lower side, the upper side of the electrical module being electrically connected to the lower side of the printed circuit board, wherein, in order for the electrical module to make electrical contact, the electrical module has electrical contacts on the upper side of the electrical module; and
an underfill material arranged between the upper side of the electrical module and the lower side of the printed circuit board in an area next to the electrical contacts,
wherein each of the electrical contacts is arranged adjacent to a side edge of the upper side of the electrical module, and an edge gap between the respective electrical contact and the adjacent side edge is sealed by an edge bond material.

2. The printed circuit board assembly of claim 1, wherein the electrical contacts are formed as strips, and
wherein the strips have a same spatial orientation.

3. The printed circuit board assembly of claim 2, wherein the strips have a same width and a same length.

4. The printed circuit board assembly of claim 2, wherein adjacent strips of the strips each have a same distance to each other.

5. The printed circuit board assembly of claim 1, wherein the electrical contacts are arranged offset to each other, such that one of the electrical contacts is arranged adjacent to a first side edge of the upper side of the electrical module, and at least one electrical contact adjacent to the one electrical contact is arranged adjacent to an opposite side edge of the upper side of the electrical module, the opposite side edge of the upper side of the electrical module being opposite the first side edge of the upper side of the electrical module.

6. The printed circuit board assembly claim 1, wherein the electrical contacts comprise three electrical contacts formed on the upper side of the electrical module.

7. The printed circuit board assembly of claim 6, wherein the three electrical contacts comprise:
a first electrical contact for a drain connection;
a second electrical contact for a source connection; and
a third electrical contact for a gate connection.

8. The printed circuit board assembly of claim 1, wherein the electrical contacts are formed as solder pads.

9. The printed circuit board assembly of claim 1, wherein the electrical contacts are arranged, such that when the underfill material that is still liquid is applied, the underfill material fills a gap between the upper side of the electrical module and the lower side of the printed circuit board in only one direction.

10. The printed circuit board assembly of claim 9, wherein the electrical contacts are formed as strips, and
wherein the electrical contacts are arranged such that when the underfill material that is still liquid is applied, the underfill material fills the gap between the upper side of the electrical module and the lower side of the printed circuit board in a direction of the strips.

11. The printed circuit board assembly of claim 9, wherein the electrical contacts are formed as strips, and
wherein the electrical contacts are arranged such that when the underfill material that is still liquid is applied, the underfill material fills the gap between the upper side of the electrical module and the lower side of the printed circuit board transversely to a direction of the strips.

12. The printed circuit board assembly of claim 1, further comprising electrical contacts formed on the lower side of the printed circuit board with an arrangement that corresponds to an arrangement of the electrical contacts on the upper side of the electrical module.

13. The printed circuit board assembly of claim 1, wherein the edge bond material is formed by an epoxy resin, an acrylic resin, a polyurethane, or a silicone.

14. The printed circuit board assembly of claim 1, wherein the electrical module comprises:
a ceramic circuit carrier that has an insulating ceramic layer and an upper metallization layer arranged on the upper side of the ceramic layer; and
an electrical component that is arranged on the ceramic circuit carrier,
wherein the electrical component is electrically contacted via the electrical contacts of the electrical module and through-holes leading out from the electrical contacts.

15. The printed circuit board assembly of claim 1, wherein the edge bond material is a different material than the underfill material.

16. The printed circuit board assembly of claim 1, wherein the edge bond material only seals the edge gap, is not located in other areas on the top side of the electrical module, or a combination thereof.
